(19) United States
(12) Patent Application Publication
(10) Pub. No.: US 2025/0113429 A1
(43) Pub. Date: Apr. 3, 2025

(54) OPTICAL MODULE AND FLEXIBLE PRINTED CIRCUIT BOARD

(71) Applicant: SUMITOMO ELECTRIC INDUSTRIES, LTD., Osaka (JP)

(72) Inventors: Seiji KUMAGAI, Osaka (JP); Taichi MISAWA, Osaka (JP); Keiji TANAKA, Osaka (JP)

(21) Appl. No.: 18/903,211

(22) Filed: Oct. 1, 2024

(30) Foreign Application Priority Data
Oct. 3, 2023 (JP) 2023-171802

(51) Int. Cl. H05K 1/02

(52) U.S. Cl. CPC H05K 1/0218; H05K 1/0277

(57) ABSTRACT

An optical module according to one embodiment includes a package including a substrate that includes a first signal wiring, and a first ground wiring formed on a second wiring layer located below a first wiring layer; and a flexible printed circuit board including an upper surface wiring layer, a lower surface wiring layer, and a base layer, and including a second signal wiring formed on the upper surface wiring layer, and a second ground wiring formed on the lower surface wiring layer. The second signal wiring includes a lead portion protruding from the base layer in a first direction. The second ground wiring includes a ground terminal located further inside the flexible printed circuit board in the first direction than the lead portion. The lead portion is connected to the first signal wiring, and the ground terminal is connected to the first ground wiring.

### CROSS-REFERENCE TO RELATED APPLICATION

This application claims priority from Japanese Patent Application No. 2023-171802, filed on Oct. 3, 2023, the entire subject matter of which is incorporated herein by reference.

### TECHNICAL FIELD

The present disclosure relates to an optical module and a flexible printed circuit board.

### BACKGROUND

Japanese Unexamined Patent Publication No. 2008-210962 describes an optical transmitter. The optical transmitter includes a driver IC, a light-emitting element, a flexible substrate, and a housing. The housing includes a plurality of electrical input units and an optical output unit. The flexible substrate has a signal line for outputting a drive signal, which is output by the driver IC, to the light-emitting element, and a plurality of DC lines. In each of the plurality of DC lines, an intermediate part has a flying lead structure in which a base material removed while leaving an electrode.

Japanese Unexamined Patent Publication No. 2012-48121 describes a modulator module including a modulator, a metal package that accommodates the modulator, and a relay substrate. The modulator includes a signal electrode and a ground electrode, and the signal electrode and the ground electrode are led to the outside through the relay substrate. The signal electrode is formed on an upper surface of the relay substrate. A lead pin is connected to the signal electrode by soldering. A flexible substrate is connected to the lead pin. The flexible substrate includes a signal electrode and a ground electrode, and a part of the ground electrode serves as a flying lead protruding from an end portion of the flexible substrate.

### SUMMARY

An optical module according to the present disclosure includes a package including a substrate that includes a first signal wiring formed on a first wiring layer, and a first ground wiring formed on a second wiring layer located below the first wiring layer; and a flexible printed circuit board including an upper surface wiring layer, a lower surface wiring layer, and a base layer disposed between the upper surface wiring layer and the lower surface wiring layer, and including a second signal wiring formed on the upper surface wiring layer, and a second ground wiring formed on the lower surface wiring layer. The second signal wiring includes a lead portion protruding from the base layer in a first direction. The second ground wiring includes a ground terminal located further inside the flexible printed circuit board in the first direction than the lead portion. The lead portion is connected to the first signal wiring, and the ground terminal is connected to the first ground wiring.

### BRIEF DESCRIPTION OF THE DRAWINGS

FIG. 1 is a plan view showing a flexible printed circuit board according to one embodiment.

FIG. 2 is a bottom view showing the flexible printed circuit board of FIG. 1.

FIG. 3 is a perspective view showing a package according to one embodiment.

FIG. 4 is a view schematically showing a cross section of the flexible printed circuit board and the package according to one embodiment.

FIG. 5A is a plan view showing the flexible printed circuit board and the package.

FIG. 5B is a cross-sectional view taken along line A-A of FIG. 5A.

FIG. 5C is a cross-sectional view taken along line B-B of FIG. 5A.

FIG. 6 is a cross-sectional view taken along line C-C of FIG. 5A.

FIG. 7 is a view schematically showing electric field distributions in an optical module according to a reference example and an optical module according to the embodiment.

FIG. 8A is a plan view showing a flexible printed circuit board and a package according to a first modification example.

FIG. 8B is a cross-sectional view taken along line A-A of FIG. 8A.

FIG. 8C is a cross-sectional view taken along line B-B of FIG. 8A.

FIG. 9A is a plan view showing a flexible printed circuit board and a package according to a second modification example.

FIG. 9B is a cross-sectional view taken along line A-A of FIG. 9A.

FIG. 9C is a cross-sectional view taken along line B-B of FIG. 9A.

### DETAILED DESCRIPTION

In the optical module, the flexible printed circuit board is connected to the package. The flexible printed circuit board includes a plurality of electrical wirings that are electrically connected to the package, and, for example, transmits high-speed signals to the package through the electrical wirings. For example, the optical module converts the high-speed signals, which are transmitted by the flexible printed circuit board, into optical signals, and outputs the optical signals to the outside. In the signal transmission by the flexible printed circuit board, low propagation loss and precise impedance matching over a frequency range up to high frequencies may be required. In this case, a reduction in the degradation of high-speed signal transmission in electrical connections with the flexible printed circuit board is required.

An object of the present disclosure is to provide an optical module and a flexible printed circuit board capable of reducing degradation of a high-speed signal in an electrical connection.

### DESCRIPTION OF EMBODIMENT OF PRESENT DISCLOSURE

First, embodiments of an optical module and a flexible printed circuit board according to the present disclosure will be listed and described below. (1) An optical module according to one embodiment includes a package including a substrate that includes a first signal wiring formed on a first wiring layer, and a first ground wiring formed on a second wiring layer located below the first wiring layer; and a flexible printed circuit board including an upper surface wiring layer, a lower surface wiring layer, and a base layer disposed between the upper surface wiring layer and the lower surface wiring layer, and including a second signal wiring formed on the upper surface wiring layer, and a second ground wiring formed on the lower surface wiring layer. The second signal wiring includes a lead portion protruding from the base layer in a first direction. The second ground wiring includes a ground terminal located further inside the flexible printed circuit board in the first direction than the lead portion. The lead portion is connected to the first signal wiring, and the ground terminal is connected to the first ground wiring.

In the optical module, the package includes the first signal wiring and the first ground wiring. The first signal wiring is formed on the first wiring layer, and the first ground wiring is formed on the second wiring layer. The flexible printed circuit board includes the upper surface wiring layer, the lower surface wiring layer, and the base layer, and the base layer is formed between the upper surface wiring layer and the lower surface wiring layer. The second signal wiring is formed on the upper surface wiring layer, and the second ground wiring is formed on the lower surface wiring layer. The second signal wiring of the flexible printed circuit board includes the lead portion protruding from the base layer, and the lead portion is connected to the first signal wiring of the substrate of the package. By being able to connect the lead portion to the first signal wiring through the exposure of the lead portion to the outside, the need to form vias for solder heat conduction in a connecting part of the flexible printed circuit board to the package can be eliminated. By not forming vias in the connecting part, impedance mismatch in high-speed signal transmission can be suppressed, and signal reflection in the signal wirings can be suppressed. Therefore, propagation loss can be reduced over a wide frequency range, and degradation of high-speed signal transmission in electrical connections with the flexible printed circuit board can be reduced.

(2) In the above (1), the first ground wiring may extend further outside the package in the first direction than the first signal wiring. In this case, in the package, the first ground wiring protrudes further outside the package than the first signal wiring, so that the connection of the flexible printed circuit board to the package can be easily performed. Therefore, the assembly of the optical module can be easily performed.

(3) In the above (1) or (2), the substrate may include a first dielectric layer located between the first wiring layer and the second wiring layer, and a second dielectric layer located on a side opposite to the first dielectric layer when viewed from the second wiring layer. An end portion of the first signal wiring in a direction opposite to the first direction may be separated from the base layer of the flexible printed circuit board, and an end portion of the second ground wiring in the first direction may be separated from the first dielectric layer. In this case, even when the flexible printed circuit board is thin, contact of the first signal wiring with the second ground wiring can be suppressed. Further, a decrease in impedance due to the first signal wiring being close to the second ground wiring can be suppressed.

(4) In any of the above (1) to (3), the upper surface wiring layer may be located on the base layer, and the lower surface wiring layer may be located under the base layer.

(5) A flexible printed circuit board according to one embodiment includes an upper surface wiring layer; a lower surface wiring layer; and a base layer disposed between the upper surface wiring layer and the lower surface wiring layer. A second signal wiring is formed on the upper surface wiring layer, and a second ground wiring is formed on the lower surface wiring layer. The second signal wiring includes a lead portion protruding from the base layer in a first direction, and the second ground wiring includes a ground terminal located further inside the flexible printed circuit board in the first direction than the lead portion. The lead portion is connected to a first signal wiring of a substrate provided in a package of an optical module, and the ground terminal is connected to the first ground wiring of the substrate.

The flexible printed circuit board includes the upper surface wiring layer, the lower surface wiring layer, and the base layer, and the base layer is formed between the upper surface wiring layer and the lower surface wiring layer. The second signal wiring is formed on the upper surface wiring layer, and the second ground wiring is formed on the lower surface wiring layer. The second signal wiring of the flexible printed circuit board includes the lead portion protruding from the base layer, and the lead portion is connected to the first signal wiring of the substrate of the package. By being able to connect the lead portion to the first signal wiring of the package through the exposure of the lead portion to the outside, the need to form vias for solder heat conduction in a connecting part of the flexible printed circuit board to the package can be eliminated. Therefore, in the flexible printed circuit board, similarly to the optical module described above, by suppressing impedance mismatch in high-speed signal transmission, signal reflection in the signal wirings can be suppressed, and propagation loss can be reduced over a wide frequency range. Therefore, degradation of high-speed signal transmission in electrical connections can be reduced.

### Details of Embodiment of Present Disclosure

A specific example of an optical module and a flexible printed circuit board according to an embodiment will be described below with reference to the drawings. It is intended that the present invention is not limited to the following examples and includes all modifications as set forth in the claims and within the scope of equivalents to the claims. In the description of the drawings, the same or corresponding elements are denoted by the same reference signs, and duplicate descriptions will be omitted as appropriate. The drawings may be depicted partially in a simplified or exaggerated manner for ease of understanding, and dimensional ratios and the like are not limited to those shown in the drawings.

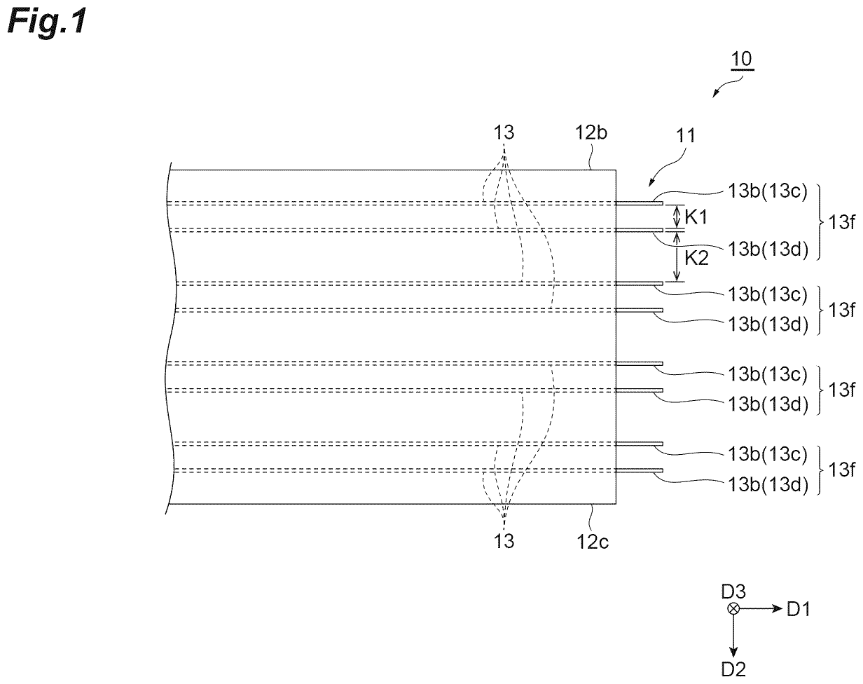

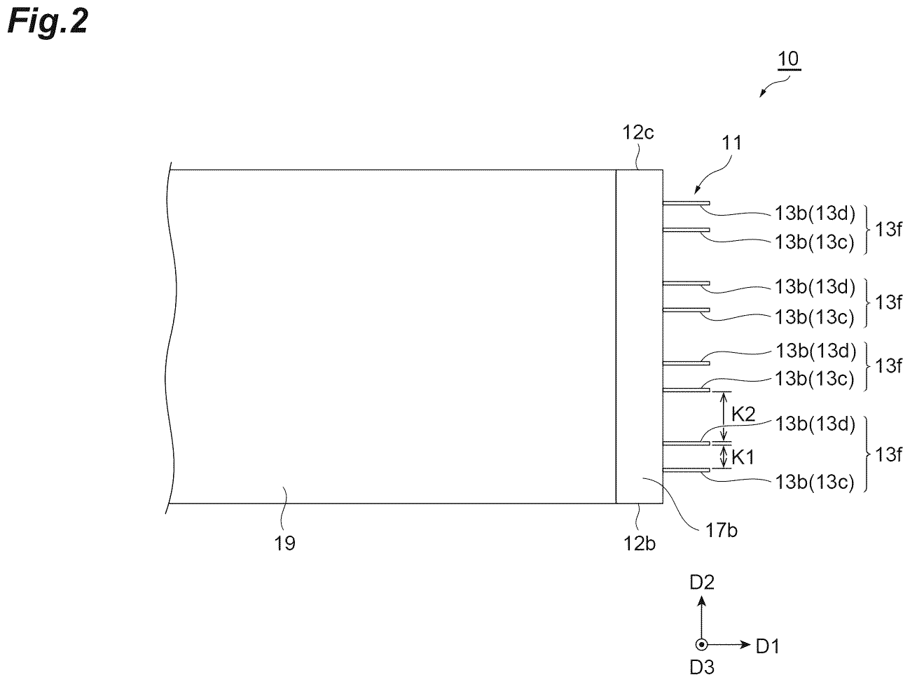

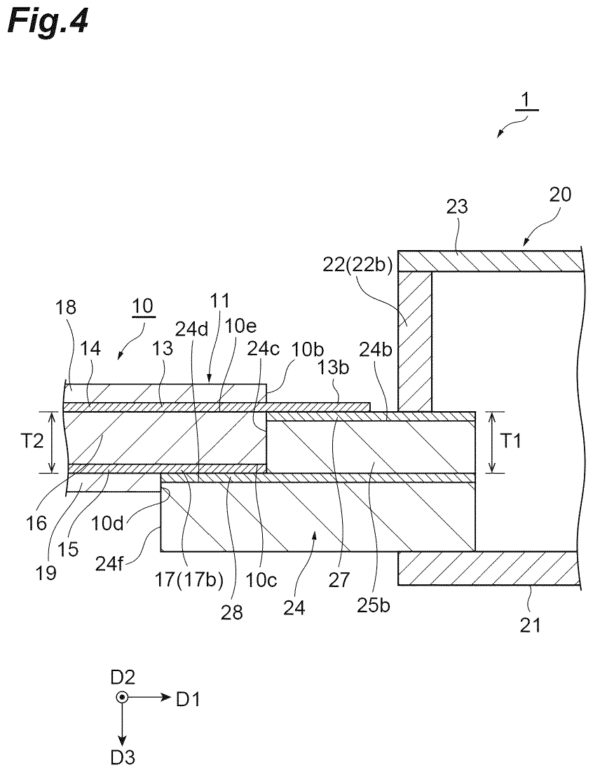

An optical module 1 according to the present embodiment includes a flexible printed circuit board 10 and a package 20 (refer to FIG. 4). FIG. 1 is a plan view showing the flexible printed circuit board 10 according to the present embodiment. FIG. 2 is a bottom view showing the flexible printed circuit board 10. As shown in FIGS. 1 and 2, the flexible printed circuit board 10 extends in both a first direction D1 and a second direction D2 intersecting the first direction D1. The first direction D1 is a longitudinal direction of the flexible printed circuit board 10, and the second direction D2 is a lateral direction of the flexible printed circuit board 10.

For example, the flexible printed circuit board 10 has a rectangular shape in a plan view. The flexible printed circuit board 10 includes a connecting part 11 at an end portion in the first direction D1. The connecting part 11 is a part for electrically connecting the flexible printed circuit board 10 to the package 20. The connecting part 11 is provided, for example, in a region extending from a first end 12b to a second end 12c in the second direction D2 at the end portion of the flexible printed circuit board 10 in the first direction D1. FIGS. 1 and 2 show the end portion of the flexible printed circuit board 10 in the first direction D1; however, the same connecting part as the connecting part 11 may be provided at an opposite end portion of the flexible printed circuit board 10 in the first direction D1.

The flexible printed circuit board 10 includes a second signal wiring 13, and the second signal wiring 13 includes a lead portion 13b protruding from the flexible printed circuit board 10 in the first direction D1. The second signal wiring 13 extends along the first direction D1. The first direction D1 is a direction in which the second signal wiring 13 extends. The flexible printed circuit board 10 includes a plurality of the lead portions 13b. Each of the plurality of lead portions 13b extends along the first direction D1. The plurality of lead portions 13b are aligned along the second direction D2. For example, the plurality of lead portions 13b include first lead portions 13c and second lead portions 13d. The flexible printed circuit board 10 includes a plurality of sets 13f, each of which is composed of the first lead portion 13c and the second lead portion 13d, and the plurality of sets 13f are aligned along the second direction D2. For example, a distance K1 from the first lead portion 13c to the second lead portion 13d is shorter than a distance K2 from the set 13f to the set 13f adjacent thereto in the second direction D2. The flexible printed circuit board 10 includes a second ground wiring 17, and the second ground wiring 17 is formed inside the lead portion 13b in the first direction D1 of the flexible printed circuit board 10.

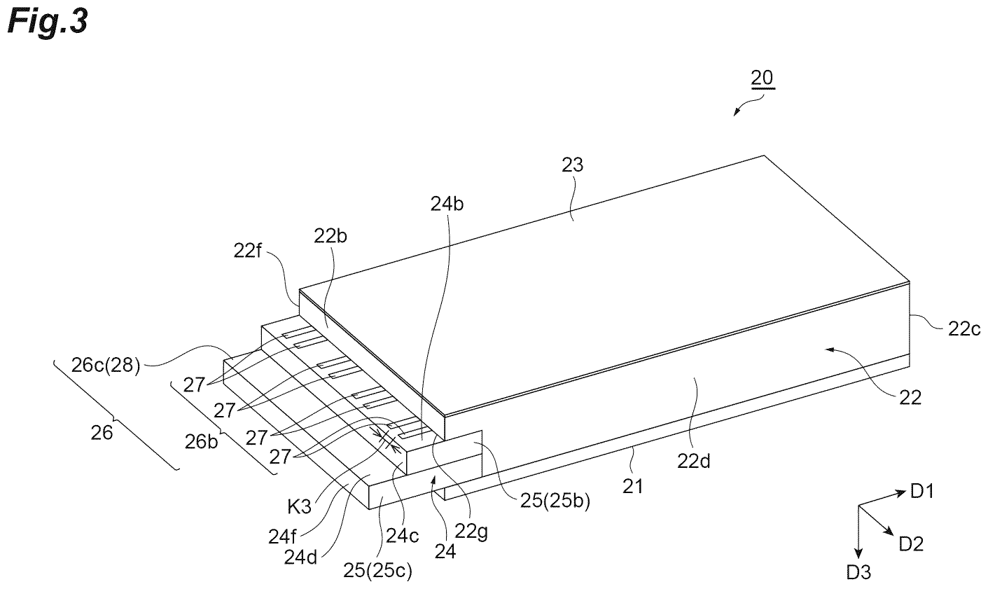

FIG. 3 is a perspective view showing the package 20. The package 20 extends in both the first direction D1 and the second direction D2, and has a thickness in a third direction D3 intersecting both the first direction D1 and the second direction D2. The package 20 accommodates, for example, a light-receiving element and a light-emitting element included in the optical module 1, and an electronic circuit connected to the light-receiving element and the light-emitting element. The package 20 has a rectangular parallelepiped shape. The package 20 includes a bottom plate 21; a side wall 22 having a rectangular frame shape and provided on the bottom plate 21; and a top plate 23 provided on the side wall 22. Hereinafter, a direction in which the top plate 23 is viewed from the bottom plate 21 may be referred to as top, upper side, or upward, and a direction in which the bottom plate 21 is viewed from the top plate 23 may be referred to as bottom, lower side, or downward. However, these directions are defined for convenience of description, and do not limit the disposition positions and directions of components.

The bottom plate 21, the side walls 22, and the top plate 23 define an internal space of the package 20. The side wall 22 has a front surface 22b and a back surface 22c facing each other in the first direction D1, and a first side surface 22d and a second side surface 22f facing each other in the second direction D2. Each of the front surface 22b and the back surface 22c extends in both the second direction D2 and the third direction D3, and each of the first side surface 22d and the second side surface 22f extends in both the first direction D1 and the third direction D3. Hereinafter, a direction in which the front surface 22b is viewed from the back surface 22c may be referred to as front, front side, or forward, and a direction in which the back surface 22c is viewed from the front surface 22b may be referred to as rear, rear side, or rearward. However, these directions are defined for convenience of description, and do not limit the disposition positions and directions of components. The first side surface 22d extends from the front surface 22b to the back surface 22c at an end portion of the package 20 in the second direction D2. The second side surface 22f extends from the front surface 22b to the back surface 22c at an opposite end portion of the package 20 in the second direction D2.

Further, the package 20 includes a substrate 24. The substrate 24 is also referred to as a feedthrough. The substrate 24 is provided at an end portion on the front side (front end portion) of the package 20. The substrate 24 is disposed to cover an opening 22g formed in the side wall 22, and an end portion on the rear side (rear end portion) of the substrate 24 faces the internal space of the package 20. The front end portion of the substrate 24 is exposed to the outside of the package 20. Therefore, the substrate 24 penetrates through the side wall 22 along the first direction D1 at the opening 22g.

For example, the substrate 24 includes a dielectric layer 25 and a wiring layer 26. The dielectric layer 25 is made of a dielectric material. For example, the dielectric layer 25 is made of alumina. The substrate 24 includes a plurality of the dielectric layers 25 and a plurality of the wiring layers 26. The plurality of dielectric layers 25 include, for example, a first dielectric layer 25b and a second dielectric layer 25c located below the first dielectric layer 25b. The second dielectric layer 25c and the first dielectric layer 25b are aligned in order from the bottom to the top along the third direction D3. The plurality of wiring layers 26 include, for example, a first wiring layer 26b and a second wiring layer 26c located below the first wiring layer 26b. The second wiring layer 26c and the first wiring layer 26b are aligned in order from the bottom to the top along the third direction D3. A thickness (length in the third direction D3) of the first wiring layer 26b and the second wiring layer 26c is, for example, 10 μm. The thickness of the first wiring layer 26b and the second wiring layer 26c may be, for example, 5 μm or more and 20 μm or less.

When viewed along the third direction D3, the second dielectric layer 25c protrudes along the first direction D1 further outward than the first dielectric layer 25b, and the second wiring layer 26c extends along the first direction D1 further outward than the first wiring layer 26b. For example, a length of the second dielectric layer 25c in the first direction D1 is larger than a length of the first dielectric layer 25b. In addition, a length of the second wiring layer 26c in the first direction D1 is larger than a length of the first wiring layer 26b. The substrate 24 includes a first signal wiring 27 formed on the first wiring layer 26b, and a first ground wiring 28 formed on the second wiring layer 26c located below the first wiring layer 26b. A plurality of the first signal wirings 27 may be formed on the first wiring layer 26b. For example, the plurality of first signal wirings 27 each extend along the first direction D1, and are arranged along the second direction D2. The plurality of first signal wirings 27 are electrically isolated from each other, and can transmit different signals. For example, two first signal wirings 27 adjacent to each other along the second direction D2 are disposed such that a distance therebetween is equal to or larger than a shortest distance K3.

FIG. 4 shows a cross-sectional view of the flexible printed circuit board 10, the side wall 22, and the substrate 24 when cut along a plane extending in both the first direction D1 and the third direction D3. As shown in FIGS. 3 and 4, the substrate 24 has a first upper surface 24b extending in both the first direction D1 and the second direction D2; a first end surface 24c extending downward from an end portion on the front side (front end) of the first upper surface 24b; a second upper surface 24d extending forward from a lower end of the first end surface 24c; and a second end surface 24f extending downward from an end portion on the front side (front end) of the second upper surface 24d. The substrate 24 has a stepped structure including the first upper surface 24b, the first end surface 24c, the second upper surface 24d, and the second end surface 24f. The stepped structure is made to include the first end surface 24c as a step by setting the length of the second dielectric layer 25c to be larger than the length of the first dielectric layer 25b in the first direction D1. The second upper surface 24d extends in both the first direction D1 and the second direction D2. As shown in FIG. 4, in the first direction D1, the flexible printed circuit board 10 is located in front of the substrate 24, and the substrate 24 is located behind the flexible printed circuit board 10.

The first upper surface 24b corresponds to an upper surface of the first dielectric layer 25b. The first wiring layer 26b is formed on the first upper surface 24b. A plurality of wirings separated from each other can be formed on the first wiring layer 26b. For example, the first wiring layer 26b includes the plurality of first signal wirings 27. The second upper surface 24d corresponds to an upper surface of the second dielectric layer 25c. The second wiring layer 26c is formed on the second upper surface 24d. A plurality of wirings separated from each other can be formed on the second wiring layer 26c. For example, the second wiring layer 26c includes the first ground wiring 28. The first ground wiring 28 may be configured as a planar pattern extending in the first direction D1 and the second direction D2, which is a so-called solid wiring. For example, the first ground wiring 28 may be configured to cover the entire upper surface of the second dielectric layer 25c. When the first ground wiring 28 is formed on a part of the second upper surface 24d of the second dielectric layer 25c, a part of the second upper surface 24d on which the first ground wiring 28 is not formed comes into contact with a lower surface of the first dielectric layer 25b.

The flexible printed circuit board 10 has a first end surface 10b extending in both the second direction D2 and the third direction D3; a base layer lower surface 10c extending forward from a lower end of the first end surface 10b; and a second end surface 10d extending downward from an end portion on the front side (front end portion) of a ground terminal 17b (to be described later) of the base layer lower surface 10c. The flexible printed circuit board 10 is connected to the substrate 24 in a state where the first end surface 10b faces the first end surface 24c of the substrate 24, the base layer lower surface 10c is placed on the second upper surface 24d of the substrate 24, and the second end surface 10d faces the second end surface 24f of the substrate 24. For example, the flexible printed circuit board 10 is connected to the substrate 24 using solder. When a lower surface protection layer 19 to be described later is not provided, the second end surface 10d is omitted.

A height T1 (length in the third direction D3) from an upper surface of the first ground wiring 28 to an upper surface of the first wiring layer 26b corresponds to a height of the step in the substrate 24. When the first signal wiring 27 is formed on the first wiring layer 26b, the height T1 corresponds to the sum of a thickness (length in the third direction D3) of the first signal wiring 27 and a thickness of the first dielectric layer 25b. The height T1 corresponds to a length of the first end surface 24c in the third direction D3. At the connecting part 11 of the flexible printed circuit board 10, a height T2 from a lower surface of a lower surface wiring layer 15 to a lower surface of an upper surface wiring layer 14 corresponds to the sum of a thickness of the lower surface wiring layer 15 and a thickness of a base layer 16. For example, when the second ground wiring 17 is formed on the lower surface wiring layer 15, the height T2 corresponds to the sum of a thickness of the second ground wiring 17 and the thickness of the base layer 16.

In the optical module 1 according to the present embodiment, the height T2 is approximately the same as the height T1. The term “approximately the same” includes a case where these heights are the same and a case where these heights are not completely the same but provide the same effect as when these heights are the same. When the height T2 is approximately the same as the height T1, for example, connection between the second signal wiring 13 and the first signal wiring 27 and between the second ground wiring 17 and the first ground wiring 28 can be reliably performed by applying solder (or adhesive) with approximately the same thickness therebetween.

The flexible printed circuit board 10 includes the upper surface wiring layer 14, the lower surface wiring layer 15, and the base layer 16 disposed between the upper surface wiring layer 14 and the lower surface wiring layer 15. The upper surface wiring layer 14 is located above the base layer 16, and the lower surface wiring layer 15 is located under the base layer 16. The base layer 16 is also referred to as a base film, and is made of, for example, polyimide. The thickness (length in the third direction D3) of the base layer 16 may be, for example, in a range of 25 to 200 μm. The base layer lower surface 10c described above corresponds to a lower surface of the base layer 16. The lower surface wiring layer 15 is formed on the base layer lower surface 10c. The lower surface wiring layer 15 is made of, for example, copper (Cu). A plurality of wirings separated from each other can be formed on the lower surface wiring layer 15. For example, the lower surface wiring layer 15 includes the second ground wiring 17. The second ground wiring 17 may be configured as a planar pattern extending in the first direction D1 and the second direction D2, which is a so-called solid wiring. For example, the second ground wiring 17 may be configured to cover the entire lower surface of the base layer 16. The upper surface wiring layer 14 is formed on an upper surface (base layer upper surface) 10e of the base layer 16. The upper surface wiring layer 14 is made of, for example, copper (Cu). A plurality of wirings separated from each other can be formed on the upper surface wiring layer 14. For example, the upper surface wiring layer 14 includes the second signal wiring 13. Namely, the second signal wiring 13 is formed on the upper surface wiring layer 14. The second ground wiring 17 is formed on the lower surface wiring layer 15. The flexible printed circuit board 10 includes the plurality of lead portions 13b, and the plurality of lead portions 13b are aligned along the second direction D2. The thickness (length in the third direction D3) of the upper surface wiring layer 14 and the lower surface wiring layer 15 is, for example, 20 μm. The thickness of the upper surface wiring layer 14 and the lower surface wiring layer 15 may be, for example, 5 μm or more and 50 μm or less.

The flexible printed circuit board 10 may further include an upper surface protection layer 18 and the lower surface protection layer 19. The upper surface protection layer 18 is formed on the upper surface wiring layer 14 to cover the upper surface wiring layer 14. The upper surface protection layer 18 protects the upper surface wiring layer 14 from the outside. In this case, the upper surface wiring layer 14 is sandwiched between the base layer 16 and the upper surface protection layer 18 in the third direction D3. The lower surface protection layer 19 is formed under the lower surface wiring layer 15 to cover the lower surface wiring layer 15. The lower surface protection layer 19 protects the lower surface wiring layer 15 from the outside. In this case, the lower surface wiring layer 15 is sandwiched between the base layer 16 and the lower surface protection layer 19 in the third direction D3. The upper surface protection layer 18 and the lower surface protection layer 19 are made of, for example, a solder resist. In addition, the upper surface protection layer 18 and the lower surface protection layer 19 may be composed of, for example, a coverlay. A thickness of the upper surface protection layer 18 and the lower surface protection layer 19 is, for example, 25 μm.

The lead portion 13b protrudes from the first end surface 10b of the flexible printed circuit board 10 in the first direction D1. The lead portion 13b is integrated with the second signal wiring 13, and protrudes from the base layer 16 in the first direction D1. The lead portion 13b also protrudes from the upper surface protection layer 18 and the lower surface protection layer 19. For example, when a plurality of the second signal wirings 13 are formed in the flexible printed circuit board 10, each of the second signal wirings 13 may include the lead portion 13b. The lead portions 13b of the plurality of second signal wirings 13 are electrically connected to the plurality of first signal wirings 27 serving as terminals. The second ground wiring 17 is located further inside the flexible printed circuit board 10 in the first direction D1 than the lead portions 13b. Namely, the end portion on the front side of the second ground wiring 17 is located in front of end portions on the front side of the lead portions 13b. Alternatively, the lead portions 13b are located between the second ground wiring 17 and the front surface 22b of the package 20 in the first direction D1.

The lead portion 13b is a terminal that is formed of an electrical wiring only without including the base layer 16, the upper surface protection layer 18, and the lower surface protection layer 19, and is referred to as a flying lead. A structure having such a terminal is referred to as a flying lead structure. The flexible printed circuit board having a flying lead structure is referred to as a flying lead flexible printed circuit (FPC). In the flexible printed circuit board 10 according to the present embodiment, a flying lead structure is formed at the end portion in the first direction D1. For example, when the electrical wiring of the lead portion 13b is made of copper (Cu), the surface of the electrical wiring may be plated with gold (Au). Further, a foundation metal layer may be formed between the copper constituting the electrical wiring and the gold plated onto the surface of the electrical wiring. The foundation metal layer is made of, for example, nickel (Ni) and palladium (Pd).

The second ground wiring 17 includes the ground terminal 17b, and the ground terminal 17b is located further inside the flexible printed circuit board 10 in the first direction D1 than the lead portions 13b. The second ground wiring 17 extends in both the first direction D1 and the second direction D2 on the base layer lower surface 10c of the flexible printed circuit board 10. For example, the second ground wiring 17 may be formed on the lower surface wiring layer 15 to cover the entirety of the base layer lower surface 10c. For example, the second ground wiring 17 may be formed as a so-called solid wiring (solid pattern). The lead portions 13b are connected to the first signal wirings 27 of the substrate 24 in a state where the lead portions 13b are placed on the first signal wirings 27. For example, the lead portion 13b is joined to the corresponding first signal wiring 27 by soldering. The ground terminal 17b is connected to the first ground wiring 28 of the substrate 24 in a state where the ground terminal 17b is placed on the first ground wiring 28. For example, the ground terminal 17b is joined to the first ground wiring 28 by soldering. The ground terminal 17b corresponds to a part of the second ground wiring 17 connected to the first ground wiring 28. For example, when the flexible printed circuit board 10 includes the lower surface protection layer 19, the ground terminal 17b is exposed from the lower surface protection layer 19. The first ground wiring 28 extends further outside the package 20 in the first direction D1 than the first signal wirings 27. Namely, the first signal wirings 27 are located between the first ground wiring 28 and the front surface 22b in the first direction D1. The first signal wirings 27 are formed on the first upper surface 24b of the substrate 24, and the first ground wiring 28 is formed on the second upper surface 24d of the substrate 24.

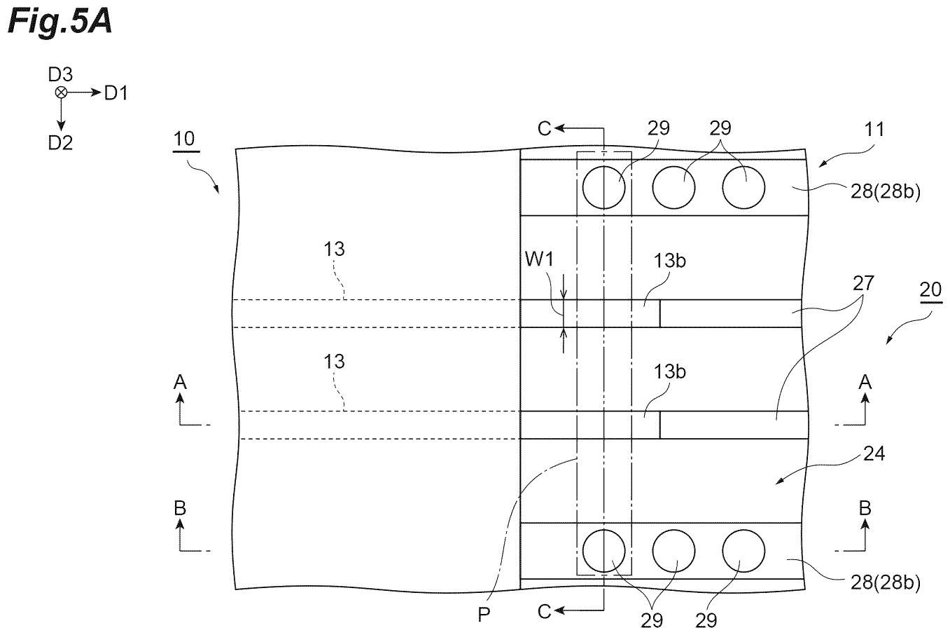

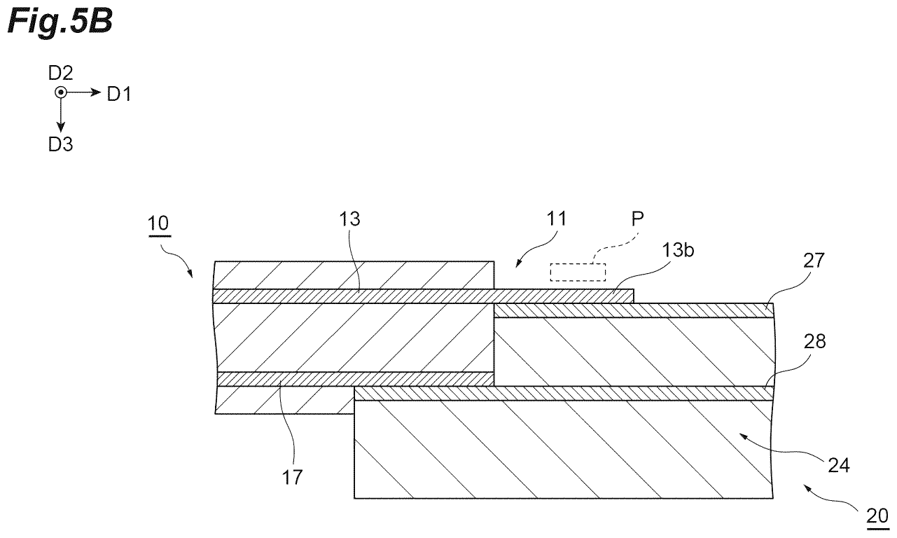

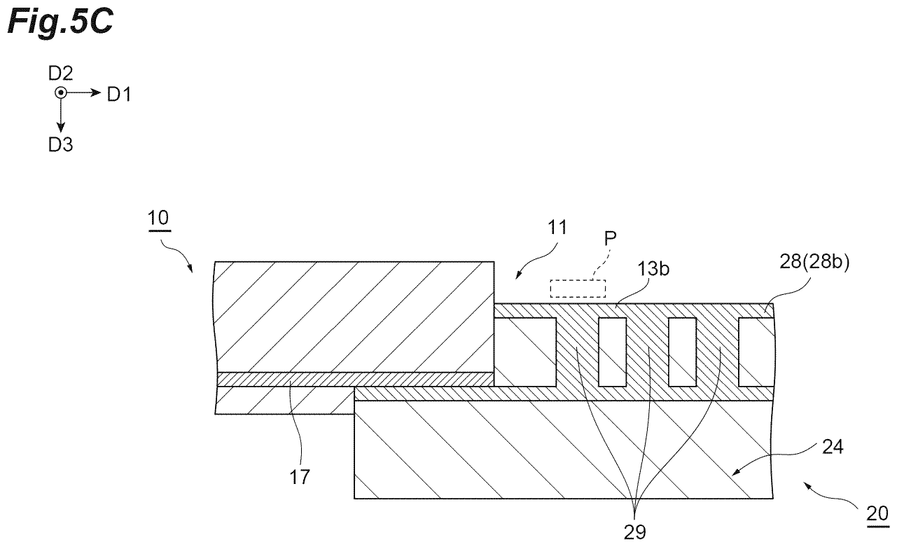

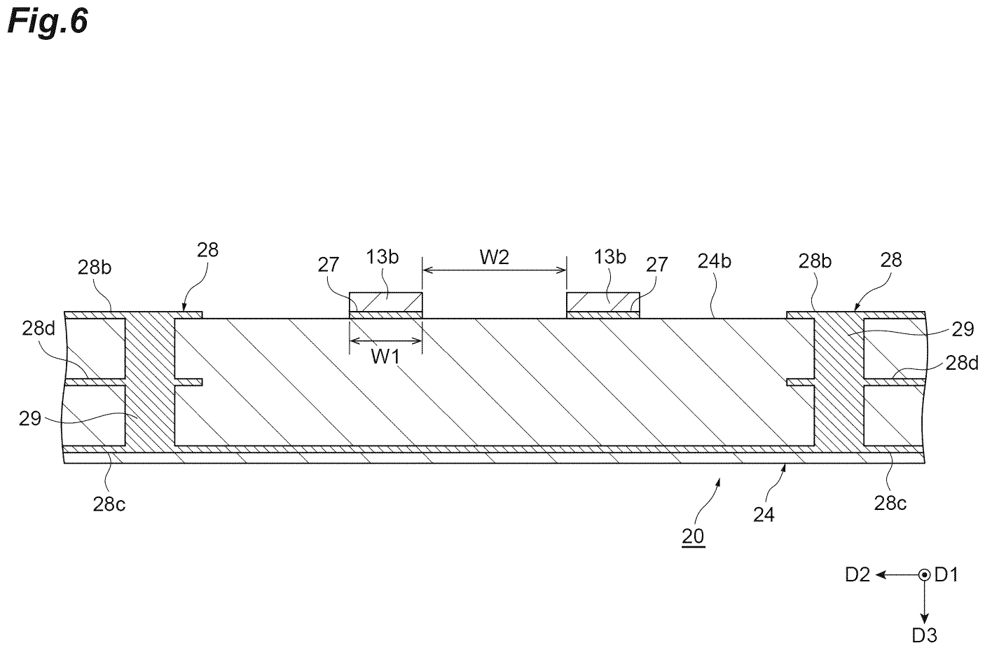

FIG. 5A is a plan view showing the connecting part 11 of the flexible printed circuit board 10. FIG. 5B is a cross-sectional view taken along line A-A of FIG. 5A. FIG. 5C is a cross-sectional view taken along line B-B of FIG. 5A. FIG. 6 is a cross-sectional view taken along line C-C of FIG. 5A. As shown in FIGS. 5A, 5B, 5C, and 6, in a plan view along the third direction D3, one first ground wiring 28, two first signal wirings 27, and one first ground wiring 28 are aligned in order along the second direction D2. Namely, the optical module 1 has a ground-signal-signal-ground (GSSG) configuration. The two first signal wirings 27 transmit, for example, a pair of complementary signals. The pair of complementary signals may be, for example, one differential signal including a positive phase signal and a reverse phase signal.

For example, on the first upper surface 24b, a thickness (length in the second direction D2) of the first ground wiring 28 is larger than a thickness of the first signal wiring 27. The lead portion 13b is disposed to overlap the first signal wiring 27. For example, a thickness W1 of the lead portion 13b is approximately the same as the thickness of the first signal wiring 27. As one example, the thickness W1 of the lead portion 13b is 100 μm. However, the thickness W1 of the lead portion 13b may not be approximately the same as the thickness of the first signal wiring 27, and can be changed as appropriate. For example, the thickness of the first signal wiring 27, a distance (spacing) between two first signal wirings 27, and a distance (spacing) between the first signal wiring 27 and the first ground wiring 28 may be set according to the characteristic impedance of a transmission line configured by the GSSG configuration. In addition, a thickness of a pair of the second signal wirings 13 connected to a pair of the first signal wirings 27 and a distance (spacing) between two second signal wirings may be set in consideration of mutual impedance matching between the pair of first signal wirings 27 and the pair of second signal wirings 13.

In the present embodiment, the second signal wiring 13 (particularly, the lead portion 13b) does not have a via for connection to the first signal wiring 27. The thickness of the second signal wiring 13 can be arbitrarily set by not providing a via in the second signal wiring 13. For example, by not providing a via in the second signal wiring 13, the thickness of the second signal wiring 13 can be made smaller than the manufacturing lower limit value of the via diameter. More specifically, when the second signal wiring 13 has a via, the thickness of the second signal wiring 13 is approximately 200 μm, whereas when the second signal wiring 13 does not have a via, the thickness W1 of the second signal wiring 13 can be reduced to approximately 100 μm. In the present embodiment, since the second signal wirings 13 can be made thinner to widen a spacing W2 between the second signal wirings 13, the impedance can be set to an appropriate value in a wider range. The characteristic impedance of a differential line by electromagnetic field analysis is 63 Ω when the second signal wiring 13 has a via, whereas in the present embodiment in which the second signal wiring 13 does not have a via, the characteristic impedance can be increased to 100Ω.

As shown in FIG. 6, the first ground wiring 28 of the substrate 24 includes, for example, an upper wiring 28b formed as the first wiring layer 26b on the first upper surface 24b, and a lower wiring 28c formed as the second wiring layer 26c located inside the substrate 24. The first ground wiring 28 of the substrate 24 may further include an intermediate wiring 28d located between the upper wiring 28b and the lower wiring 28c. The substrate 24 has a via 29 extending in the third direction D3. The inside of the via 29 is filled with, for example, metal. The via 29 extends from the upper wiring 28b through the intermediate wiring 28d to the lower wiring 28c. As one example, the via 29 has a columnar shape extending along the third direction D3. The substrate 24 has a plurality of the vias 29, and the plurality of vias 29 are aligned along the first direction D1. The first ground wiring 28 includes the upper wiring 28b and the lower wiring 28c that are electrically connected to each other by the vias 29. The first ground wiring 28 may include a wiring formed in the intermediate wiring 28d shown in FIG. 6. In FIG. 5C, the intermediate wiring 28d is omitted.

For example, in each upper wiring 28b, a plurality of the vias 29 are aligned at equal spacings along the first direction D1. For example, among a plurality of the upper wirings 28b, the positions of the vias 29 of each upper wiring 28b in the first direction D1 are the same as the positions of the vias 29 of the other upper wirings 28b in the first direction. Therefore, in a plan view along the third direction D3, a plurality of the vias 29 are aligned along the second direction D2. The connection of the second ground wiring 17 to the first ground wiring 28 and the connection of the lead portions 13b to the first signal wirings 27 are performed using solder. For example, by heating a heater tool P extending along the second direction D2, and applying the heater tool P to the vias 29 and the lead portions 13b from above, heat of the heater tool P is transferred to the first ground wiring 28, the vias 29, the second ground wiring 17, the lead portions 13b, and the first signal wirings 27. Accordingly, the solder connection of the second ground wiring 17 to the first ground wiring 28 and the solder connection of the lead portions 13b to the first signal wirings 27 can be performed at once.

Next, actions and effects obtained from the optical module 1 and the flexible printed circuit board 10 according to the present embodiment will be described. In the optical module 1, the package 20 includes the first signal wirings 27 and the first ground wiring 28. The first signal wirings 27 are formed on the first wiring layer 26b, and the first ground wiring 28 is formed on the second wiring layer 26c. The flexible printed circuit board 10 includes the upper surface wiring layer 14, the lower surface wiring layer 15, and the base layer 16, and the base layer 16 is formed between the upper surface wiring layer 14 and the lower surface wiring layer 15. The upper surface wiring layer 14 is formed on the upper surface 10e of the base layer (base layer upper surface), and the lower surface wiring layer 15 is formed on the lower surface 10c of the base layer (base layer lower surface). The second signal wirings 13 are formed on the upper surface wiring layer 14, and the second ground wiring 17 is formed on the lower surface wiring layer 15. The second signal wirings 13 of the flexible printed circuit board 10 include the lead portions 13b as terminals, the lead portions 13b protruding from the base layer 16, and the lead portions 13b are electrically connected to the first signal wirings 27 of the substrate 24 of the package 20. By exposing the lead portions 13b to the outside, and connecting the lead portions 13b to the first signal wirings 27, the need to form vias for solder heat conduction in the connecting part 11 of the flexible printed circuit board 10 to the package 20 can be eliminated. By not forming vias in the connecting part 11, the characteristic impedance can be adjusted over a wider range, impedance mismatch between the signal wirings can be suppressed, and signal reflection between the signal wirings can be suppressed. Therefore, propagation loss can be reduced over a wide frequency range, and degradation of high-speed signal transmission in electrical connections with the flexible printed circuit board 10 can be reduced.

As described above, the end portion on the front side (front end portion) of the first ground wiring 28 may be located further in front of the package 20 in the first direction D1 than the first signal wirings 27. In this case, in the package 20, the first ground wiring 28 protrudes further outside the package 20 than the first signal wirings 27, so that the connection of the flexible printed circuit board 10 to the package 20 can be easily performed. Therefore, the assembly of the optical module 1 can be easily performed.

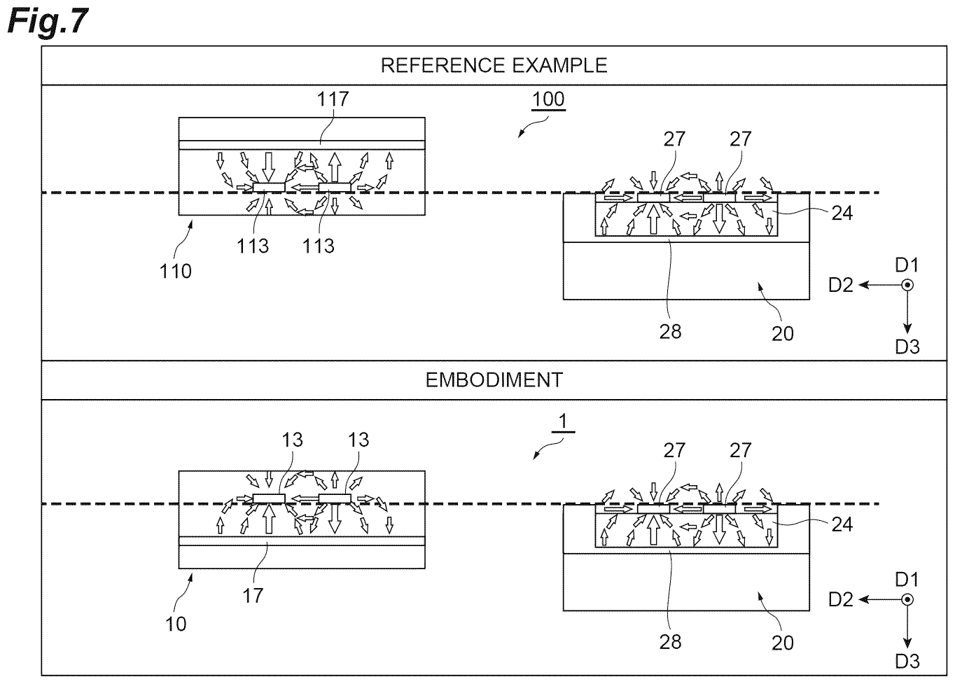

FIG. 7 schematically shows the directions of electric fields of differential signals transmitted from the flexible printed circuit boards 10 and 110 to the package 20 in the optical module 1 according to the embodiment and the optical module 100 according to a reference example. In FIG. 7, the differential signals propagate along a direction perpendicular to the plane of the paper. In the optical module 1, the flexible printed circuit board 10 is connected to the package 20 in a state where the first signal wirings 27 of the substrate 24 are located above the first ground wiring 28 and the second signal wirings 13 of the flexible printed circuit board 10 are located above the second ground wiring 17.

Therefore, in a state where the flexible printed circuit board 10 is connected to the package 20, the height (position in the third direction D3) of the second ground wiring 17 formed on the lower surface wiring layer 15 is approximately the same as the height of the first ground wiring 28 formed on the second wiring layer 26c, and the height of the second signal wirings 13 formed on the upper surface wiring layer 14 is approximately the same as the height of the first signal wirings 27 formed on the first upper surface. Meanwhile, in the optical module 100 according to the reference example, since no lead portion is provided, terminals are provided inside a flexible printed circuit board 110. Therefore, second signal wirings 113 exposed toward the bottom of the flexible printed circuit board 110 is located below a second ground wiring 117. The flexible printed circuit board 110 is connected to the package 20 in a state where the second signal wirings 113 and the second ground wiring 117 are upside down compared to the flexible printed circuit board 10.

In the optical module 100, the direction of the electric field from the first signal wirings 27 toward the first ground wiring 28 in the package 20 is reversed to the direction of the electric field from the second signal wirings 113 toward the second ground wiring 117 in the flexible printed circuit board 110. Further, the direction of the electric field from the first ground wiring 28 toward the first signal wirings 27 in the package 20 is reversed to the direction of the electric field from the second ground wiring 117 toward the second signal wirings 113 in the flexible printed circuit board 110.

Meanwhile, in the optical module 1, the direction of the electric field from the first signal wirings 27 toward the first ground wiring 28 in the package 20 is the same as the direction of the electric field from the second signal wirings 13 toward the second ground wiring 17 in the flexible printed circuit board 10. Furthermore, the direction of the electric field from the first ground wiring 28 toward the first signal wirings 27 in the package 20 is the same as the direction of the electric field from the second ground wiring 17 toward the second signal wirings 13 in the flexible printed circuit board 10.

The reversal of the directions of the electric fields in the optical module 100 described above is unlikely to be a problem if the frequency component is, for example, approximately 50 GHz or less. However, for a frequency component of more than 50 GHz, in the optical module 100, there is a possibility that signal waveform quality is degraded due to electromagnetic radiation or the like caused by disturbances in electric field distribution. Meanwhile, in the optical module 1, since the directions of the electric fields are the same as described above, the degradation of signal waveform quality can be reduced.

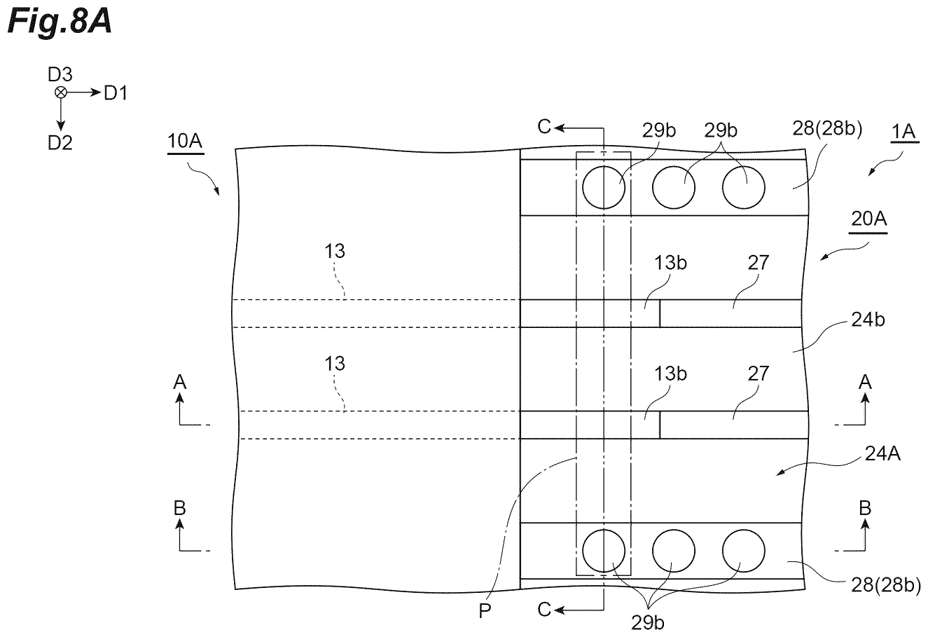

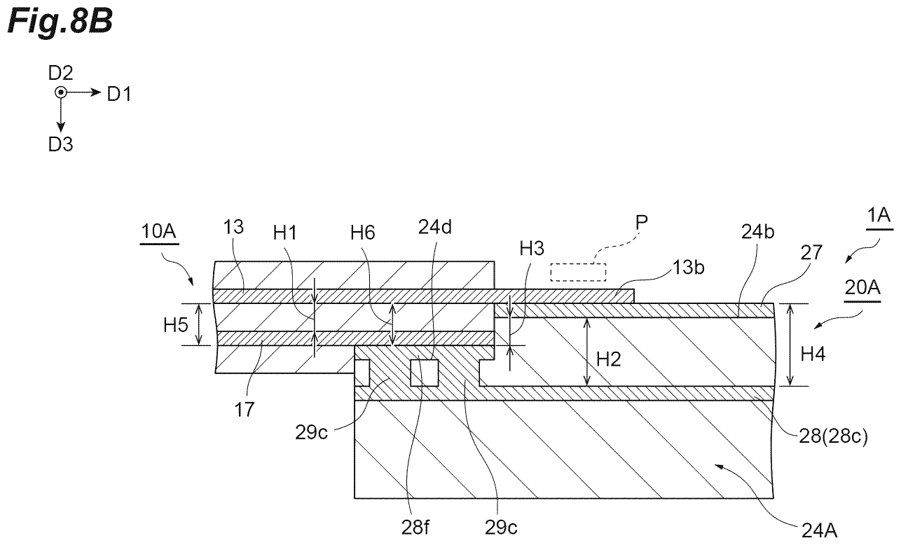

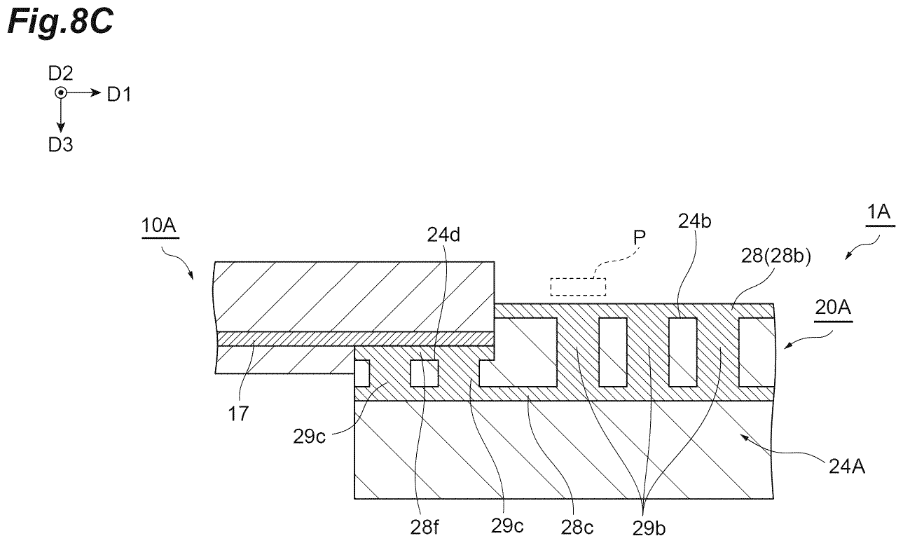

Next, an optical module 1A according to a first modification example will be described with reference to FIGS. 8A, 8B, and 8C. A partial configuration of the optical module 1A is the same as a partial configuration of the optical module 1 described above. Therefore, hereinafter, the same configurations as those in the optical module 1 are denoted by the same reference signs, and duplicated descriptions will be omitted as appropriate.

The optical module 1A includes a flexible printed circuit board 10A and a package 20A that are different in shape from the flexible printed circuit board 10 and the package 20 described above. The first ground wiring 28 of a substrate 24A of the package 20A includes the upper wiring 28b formed on the first upper surface 24b; the lower wiring 28c located inside the substrate 24A; and an intermediate wiring 28f formed on the second upper surface 24d. The upper wiring 28b is formed on a first wiring layer similarly to the package 20, and the lower wiring 28c is formed on a second wiring layer similarly to the package 20. The substrate 24A includes a first via 29b extending from the upper wiring 28b to the lower wiring 28c, and a second via 29c extending from the intermediate wiring 28f to the lower wiring 28c. Each of the first via 29b and the second via 29c is filled with metal. The package 20A differs from the package 20 in that the package 20A includes an intermediate wiring layer between the first wiring layer and the second wiring layer, the intermediate wiring 28f is formed on the second upper surface 24d by the intermediate wiring layer, and the intermediate wiring 28f is connected to the lower wiring 28c through the second via 29c.

The optical module 1A differs from the optical module 1 described above in that the optical module 1A includes the second via 29c extending downward from the intermediate wiring 28f. Namely, in the substrate 24A of the optical module 1A, the first ground wiring 28 (intermediate wiring 28f) is formed at a position higher than the lower wiring 28c. Accordingly, the step between the first upper surface 24b and the second upper surface 24d of the substrate 24A can be made smaller, and the flexible printed circuit board 10A in which the base layer 16 has a thinner thickness than in the flexible printed circuit board 10 can be connected. In such a manner, by being able to set a distance in the third direction D3 between signal wirings and a ground wiring separately for the substrate 24A and the flexible printed circuit board 10A, the adjustment of the characteristic impedance of a transmission line formed by each of the signal wirings can be freely performed.

For example, by applying the heater tool P to the first via 29b from above, the first via 29b extending along the second direction D2, heat of the heater tool P is transferred from the first via 29b through the lower wiring 28c and the second via 29c to the intermediate wiring 28f. Accordingly, the solder connection of the second ground wiring 17 to the intermediate wiring 28f and the solder connection of the lead portions 13b to the first signal wirings 27 can be performed at once.

A distance H1 in the third direction D3 between the second signal wirings 13 and the second ground wiring 17 in the flexible printed circuit board 10A is smaller than a distance H2 in the third direction D3 between the first signal wirings 27 and the first ground wiring 28 in the substrate 24A. For example, the distance H1 is 100 μm, and the distance H2 is 200 μm. The distance H1 is approximately the same as a distance H3 in the third direction D3 between the first signal wirings 27 and the intermediate wiring 28f in the substrate 24A.

In addition, a distance H4 in the third direction D3 from the upper surface of the first ground wiring 28 to an upper surface of the first signal wiring 27 in the substrate 24A is larger than a distance H5 in the third direction D3 from a lower surface of the second ground wiring 17 to a lower surface of the second signal wiring 13 in the flexible printed circuit board 10A. When the distance in the third direction D3 from an upper surface of the intermediate wiring 28f to the upper surface of the first signal wiring 27 is a distance H6, a height from an upper surface of the lower wiring 28c to the upper surface of the intermediate wiring 28f is approximately the same as a difference between the distance H4 and the distance H6. As described above, in the optical module 1A according to the first modification example, the flexible printed circuit board 10A having a thinner base material can be connected to the package 20A. In such a manner, by being able to set the distance H2 and the distance H1 to different values for the substrate 24A and the flexible printed circuit board 10A, the adjustment of the characteristic impedances of transmission lines formed in each can be more freely performed without the restriction of setting the distance H2 and the distance H1 to the same value.

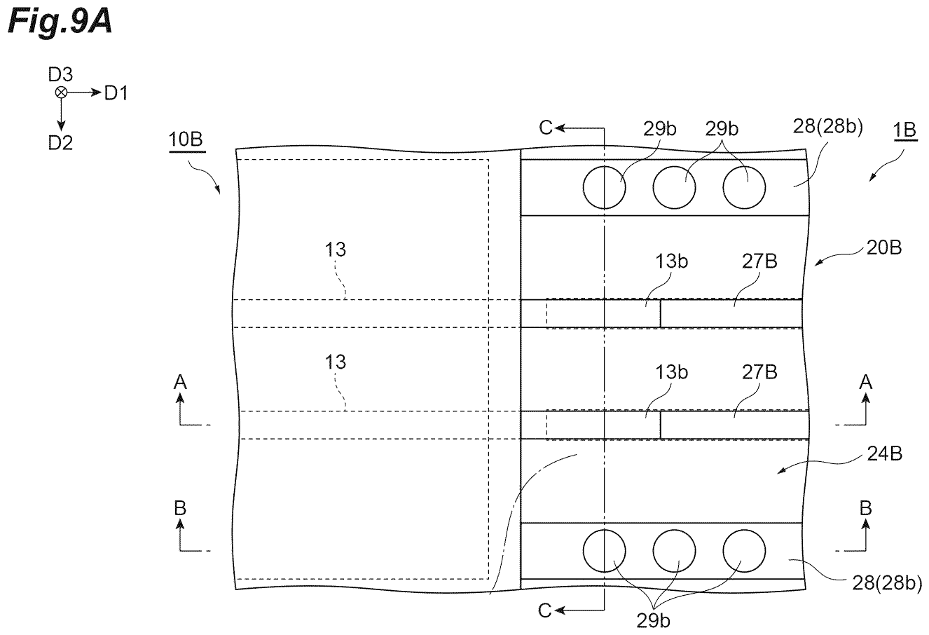

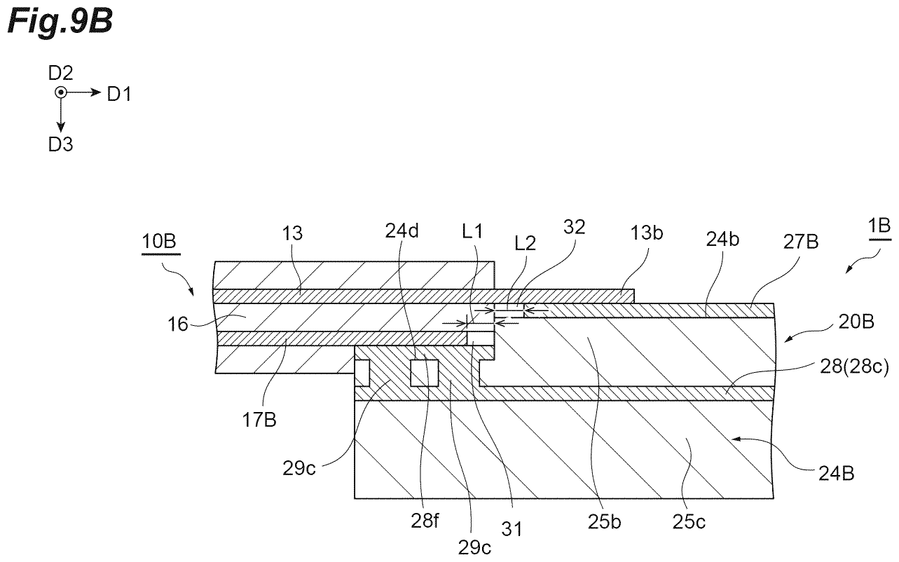

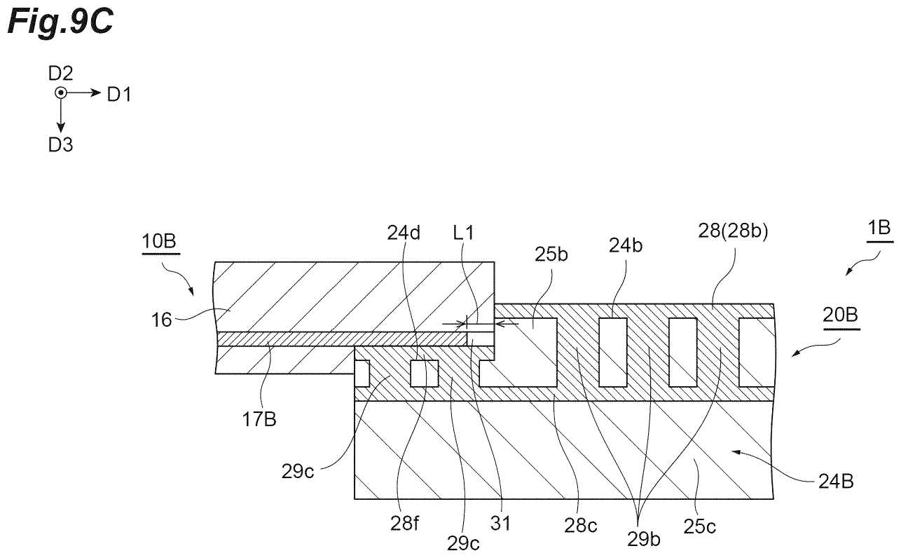

Subsequently, an optical module 1B according to a second modification example will be described with reference to FIGS. 9A, 9B, and 9C. The optical module 1B is the same as the optical module 1A, except that the optical module 1B includes offset portions 31 and 32 to be described later. In the optical module 1B, in a state where a flexible printed circuit board 10B is connected to a substrate 24B of a package 20B, a second ground wiring 17B of the flexible printed circuit board 10B is separated from the first dielectric layer 25b of the substrate 24B along the first direction D1. In a state where the flexible printed circuit board 10B is connected to the substrate 24B, a first signal wiring 27B of the substrate 24B is separated from the base layer 16 of the flexible printed circuit board 10B in the first direction D1.

A rear end portion of the second ground wiring 17B is located further inside (forward) the flexible printed circuit board 10B in the first direction D1 than a rear end portion of the base layer 16. A front end portion of the first signal wiring 27B is located further inside (rearward) the substrate 24B in the first direction D1 than a front end portion of the first dielectric layer 25b. As a result, the offset portion 31 is formed between the second ground wiring 17B and the first dielectric layer 25b, and the offset portion 32 is formed between the first signal wiring 27B and the base layer 16. For example, the offset portion 31 is a region in the flexible printed circuit board 10B where a rear end portion of the second ground wiring 17B is removed, and the offset portion 32 is a region in the substrate 24B where a front end portion of the first signal wiring 27B is removed.

As one example, the offset portion 31 is a space formed between the second ground wiring 17B and the first dielectric layer 25b, and the offset portion 32 is a space formed between the first signal wiring 27B and the base layer 16. However, the offset portion 31 and the offset portion 32 may not be hollow, and the inside thereof may be filled with, for example, a resin material. For example, a length L1 of the offset portion 31 in the first direction D1 and a length L2 of the offset portion 32 in the first direction D1 are 50 μm or more and 200 μm or less (100 μm as one example).

As described above, in the optical module 1B according to the second modification example, the substrate 24B includes the first dielectric layer 25b located between the first wiring layer 26b and the second wiring layer 26c, and the second dielectric layer 25c located on a side opposite to the first dielectric layer 25b when viewed from the second wiring layer 26c. The front end portion of the first signal wiring 27B is separated from the base layer 16 of the flexible printed circuit board 10B. The rear end portion of the second ground wiring 17B is separated from the first dielectric layer 25b. In this case, even when the flexible printed circuit board 10B is thin, contact of the first signal wiring 27B with the second ground wiring 17B can be suppressed. Further, a decrease in the impedance of the signal wiring constituting a transmission line, which is due to the first signal wiring 27B being close to the second ground wiring 17B, can be suppressed.

The embodiment and various modification examples of the optical module and the flexible printed circuit board according to the present disclosure have been described above. However, the present invention is not limited to the embodiment or the various modification examples described above, and can be modified as appropriate within the scope of the concept described in the claims. In addition, the optical module and the flexible printed circuit board according to the present disclosure may be a combination of a plurality of examples from the embodiment, the first modification example, and the second modification example described above. For example, the configuration, shape, size, material, number, and disposition mode of each portion of the optical module and the flexible printed circuit board according to the present disclosure are not limited to the embodiment or the modification examples described above, and can be modified as appropriate. For example, in the embodiment described above, the flexible printed circuit board 10 including two wiring layers including the upper surface wiring layer 14 and the lower surface wiring layer 15 has been described. However, the flexible printed circuit board may include three or more wiring layers. The same applies to the substrate of the package.

What is claimed is:

1. An optical module comprising:
a package including a substrate that includes a first signal wiring formed on a first wiring layer, and a first ground wiring formed on a second wiring layer located below the first wiring layer; and
a flexible printed circuit board including an upper surface wiring layer, a lower surface wiring layer, and a base layer disposed between the upper surface wiring layer and the lower surface wiring layer, and including a second signal wiring formed on the upper surface wiring layer, and a second ground wiring formed on the lower surface wiring layer,
wherein the second signal wiring includes a lead portion protruding from the base layer in a first direction,
the second ground wiring includes a ground terminal located further inside the flexible printed circuit board in the first direction than the lead portion,
the lead portion is connected to the first signal wiring, and
the ground terminal is connected to the first ground wiring.

2. The optical module according to claim 1,
wherein the first ground wiring is located further outside the package in the first direction than the first signal wiring.

3. The optical module according to claim 1,
wherein the substrate includes a first dielectric layer located between the first wiring layer and the second wiring layer, and a second dielectric layer located on a side opposite to the first dielectric layer when viewed from the second wiring layer,
an end portion of the first signal wiring in a direction opposite to the first direction is separated from the base layer of the flexible printed circuit board, and
an end portion of the second ground wiring in the first direction is separated from the first dielectric layer.

4. The optical module according to claim 1,
wherein the upper surface wiring layer is located on the base layer, and the lower surface wiring layer is located under the base layer.

5. A flexible printed circuit board comprising:
an upper surface wiring layer;
a lower surface wiring layer; and
a base layer disposed between the upper surface wiring layer and the lower surface wiring layer,
wherein a second signal wiring is formed on the upper surface wiring layer,
a second ground wiring is formed on the lower surface wiring layer,
the second signal wiring includes a lead portion protruding from the base layer in a first direction,
the second ground wiring includes a ground terminal located further inside the flexible printed circuit board in the first direction than the lead portion,
the lead portion is connected to a first signal wiring of a substrate provided in a package of an optical module, and
the ground terminal is connected to the first ground wiring of the substrate.
